(19) United States
(12) Patent Application Publication
(10) Pub. No.: US 2013/0075907 A1
(43) Pub. Date: Mar. 28, 2013

(54) Interconnection Between Integrated Circuit and Package

(71) Applicant: Mengzhi PANG, Cupertino, CA (US)

(72) Inventor: Mengzhi PANG, Cupertino, CA (US)

(73) Assignee: Broadcom Corporation, Irvine, CA (US)

(21) Appl. No.: 13/243,078

(22) Filed: Sep. 23, 2011

(51) Int. Cl. H01L 23/48; H01L 21/44; H01L 21/768; H01L 21/60

(52) U.S. Cl. 257/741; 438/613; 438/612; 438/618; 257/E23.011; 257/E21.575; 257/E21.507

(57) ABSTRACT

In order to achieve finer bump interconnect pitch for integrated circuit packaging, while relieving pressure-induced delamination of upper layer dielectric films, the under bump metallurgy of the present invention provides a pressure distribution pedestal upon which a narrower copper pillar is disposed. A solder mini-bump is disposed on the upper exposed portion of the copper pillar, wherein the solder is softer than the copper pillar. The radius of the copper pillars is selected such that lateral deformation of the solder mini-bumps during final assembly does not form undesired conductive bridges between adjacent pillars.

### FIELD OF THE INVENTION

The present invention relates generally to integrated circuits and packaging of integrated circuits.

### BACKGROUND

Advances in semiconductor manufacturing technologies have resulted in dramatically increased circuit packing densities and higher speeds of operation. In turn, these advances have provided designers with the ability to produce many computational, communication, and memory functions that were not previously practical. Advances in digital systems architecture, in combination with the advances in the speed and density of semiconductors, have resulted in the production of integrated circuits having a very large number of input, output, input/output, and power terminals.

There are many different manufacturing processes for producing a finished integrated circuit, and almost all of these processes have certain aspects in common. For example, it is common to fabricate integrated circuits on roughly circular semiconductor substrates, or wafers. Further, it is common to form such integrated circuits so that conductive regions disposed on, or close to, the uppermost layers of the integrated circuits are available to act as terminals for connection to various electrical elements disposed in, or on, the lower layers of those integrated circuits. An example of such conductive regions is the bond pads that are very well known in the field of integrated circuits.

In modern high-speed integrated circuits it is common to employ low-k dielectric materials as inter-layer dielectrics (ILDs). Such low-k, extreme-low-k, and ultra-low-k ILDs generally have reduced mechanical strength as compared to conventional dielectric material such as non-porous silicon dioxide. While the use of low-k dielectrics tends to improve the operational speed and reduce the power consumption of integrated circuits, the reduced mechanical strength and delamination tendencies of such dielectric materials must be considered when attaching the integrated circuit to a substrate.

It is also well-known that the cost of an integrated circuit is related to its size, that is its area. Generally, large chips are more expensive than small chips. So there is an incentive to keep the area of a chip as small as is practical. On the other hand, in order to get the best performance from an integrated circuit, it is often necessary to provide as many electrical connections as possible between the chip and external components. These electrical connections with the chip are formed between the bond pads on the integrated circuits, and connection terminals disposed on substrates such as packages, interposers, or boards. In order to increase the number of connections between an integrated circuit and a substrate, the size of the physical interconnection structures and the spacing between them should be reduced as much as possible.

What is needed are methods and structures for reducing the size of physical interconnection structures without creating a point load beyond the carrying capacity of underlying low-k dielectric materials; and wherein those physical structures support a narrow pitch while avoiding solder bridging.

### BRIEF DESCRIPTION OF THE DRAWINGS

Embodiments of the invention are described with reference to the accompanying drawings. In the drawings, like reference numbers indicate identical or functionally similar elements. Additionally, the left most digit(s) of a reference number identifies the drawing in which the reference number first appears.

FIG. 1 is a cross-sectional view of a portion of a wafer having a plurality of integrated circuits fabricated thereon, with a topside passivation layer covering the wafer with the exception of the pad openings in the topside, these openings exposing a portion of a bond pad.

FIG. 2 shows the structure of FIG. 1 after a first dielectric layer has been formed over the topside and exposed bond pads, and then patterned to open a trench, the trench having dimensions that substantially define the dimensions of a force-redistributing base of an interconnection bump in accordance with the present invention.

FIG. 3 shows the structure of FIG. 2 after a seed layer has been formed on the exposed surfaces of the wafer, and a Cu metal layer has been plated up over the seed layer.

FIG. 4 shows the structure of FIG. 3 after excess Cu has been removed, leaving Cu in the trench in the desired dimensions for the force-redistributing base of the interconnection bump.

FIG. 5 shows the structure of FIG. 4 after a second dielectric layer has been formed over exposed surfaces of the wafer, i.e., the first dielectric layer and a top surface of the and then patterned to open a trench, the trench having dimensions that substantially define the dimensions of a pillar of an interconnection bump in accordance with the present invention.

FIG. 6 shows the structure of FIG. 5 after the seed layer has been formed on the exposed surfaces of the wafer i.e., the second dielectric layer and that portion of the base exposed by the trench in the second dielectric layer, and a Cu metal layer has been plated up over the seed layer.

FIG. 7 shows the structure of FIG. 6 after excess Cu has been removed, leaving Cu in the trench in the desired dimensions for the pillar of the interconnection bump in accordance with the present invention.

FIG. 8 shows the structure of FIG. 7 after a solder cap has been formed on the top surface of the pillar and the second and first dielectric layers have been etched away.

FIG. 9 shows the structure of FIG. 8 after a contact terminal of a substrate is bonded with the solder cap.

FIG. 10 shows the structure of FIG. 9 after an underfill material has been disposed between the substrate and the integrated circuit.

FIG. 11 shows an assembly similar to that of FIG. 9 where two base/column/cap structures are shown bonded with a corresponding pair of connection terminals of a substrate, and further illustrating the relative spacings of the columns and the after-bonding dimensions of the solder caps.

FIG. 12 is a cross-sectional view of another embodiment of the present invention wherein a polymer passivation layer is disposed between the topside passivation layer and the underside of the wing sections of the base portion of the interconnect bump in accordance with the present invention.

### DETAILED DESCRIPTION

The following Detailed Description refers to accompanying drawings to illustrate exemplary embodiments consistent with the invention. References in the Detailed Description to “one exemplary embodiment,” “an illustrative embodiment”, “an exemplary embodiment,” and so on, indicate that the exemplary embodiment described may include a particular feature, structure, or characteristic, but every exemplary embodiment may not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications may be made to the exemplary embodiments within the spirit and scope of the invention. Therefore, the Detailed Description is not meant to limit the invention. Rather, the scope of the invention is defined only in accordance with the following claims and their equivalents.

The following Detailed Description of the exemplary embodiments will so fully reveal the general nature of the invention that others can, by applying knowledge of those skilled in relevant art(s), readily modify and/or adapt for various applications such exemplary embodiments, without undue experimentation, without departing from the spirit and scope of the invention. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

As indicated above, integrated circuits increasingly have more functions and therefore have more connections that must be made between the integrated circuit and other electrical elements. Such interconnections are typically made by electrically connecting a bond pad on the integrated circuit to a contact terminal of a substrate, including but not limited to a package, an interposer, and a board, by disposing an interconnection structure between the bond pad and the contact terminal. In many circumstances the physical connection requires a solder bump between the interconnection structure of the integrated circuit, and the contact terminal of the substrate. It is noted that a lateral deformation of the solder bump may occur when the interconnection structure of the integrated circuit, and the contact terminal of the substrate are actually connected. Therefore the space consumed by the lateral deformation of the solder limits the pitch of conventional interconnection structures.

Generally, embodiments of the present invention provide an interconnection structure suitable for fine pitch interconnections between a chip and a substrate. Various embodiments of the present invention provide a narrow electrically conductive pillar with a solder cap at a distal end thereof. The narrow pillar limits the size of the solder cap, and provides expansion space for lateral deformation. Embodiments of the present invention also compensates for the increased pressure that a narrow pillar places on underlying low-k dielectric materials of the integrated circuit. Various embodiments of the present invention provide a force-redistributing base portion upon which the pillar rests. In this way, the lateral deformation of the solder is addressed by the small geometry of the pillar, while the damaging pressure of a narrow pillar is mitigated by disposing a force-redistributing base between the pillar and the bond pad.

In some embodiments, two passivation layers are disposed between the extended “wing” portions of the force-redistributing base and the low-k dielectric materials of the integrated circuit. By way of example, and not limitation, a polymer-based passivation layer, such as polyimide, is disposed over a conventional silicon nitride passivation layer.

Terminology

The terms, chip, die, integrated circuit, semiconductor device, and microelectronic device, are often used interchangeably in the field of electronics. The present invention is applicable to all the above as these terms are generally understood in the field.

With respect to chips, it is common that power, ground, and various signals may be coupled between them and other circuit elements via physical, electrically conductive connections. Such a point of connection may be referred to as an input, output, input/output (I/O), terminal, line, pin, pad, port, interface, or similar variants and combinations. Although connections between and amongst chips are commonly made by way of electrical conductors, those skilled in the art will appreciate that chips and other circuit elements may alternatively be coupled by way of optical, mechanical, magnetic, electrostatic, and electromagnetic interfaces.

Bond pad refers to a region of electrically conductive material, typically a metal, a metal alloy, or a stack structure including several layers of metals and/or metal alloys, that are present, typically, at the uppermost layer of conductive material of an integrated circuit. Such pads are also sometimes referred to as contact pads, chip pads, or test pads, and these terms are well understood in the integrated circuit industry. Bond pads are terminals which provide for electrical connection to be made between the integrated circuit and external devices.

The terms metal line, trace, wire, conductor, signal path and signaling medium are all related. The related terms listed above, are generally interchangeable, and appear in order from specific to general. In this field, metal lines are sometimes referred to as traces, wires, lines, interconnect or simply metal. Metal lines, such as aluminum (Al), copper (Cu), an alloy of Al and Cu, an alloy of Al, Cu and silicon (Si), tungsten (W), and nickel (Ni) are conductors that provide signal paths for coupling or interconnecting, electrical circuitry. Other conductors, both metal and non-metal are available in microelectronic devices. Materials such as doped polysilicon, doped single-crystal silicon (often referred to simply as diffusion, regardless of whether such doping is achieved by thermal diffusion or ion implantation), titanium (Ti), molybdenum (Mo), and refractory metal silicides are examples of other conductors.

The term vertical, as used herein, means substantially perpendicular to the surface of a substrate.

The acronym UBM stands for under-bump metallization. More particularly, JEDEC, defines under-bump metallization as a patterned, thin-film stack of material that provides an electrical connection from the silicon die to a solder bump; a barrier function to limit unwanted diffusion from the bump to the silicon die; and a mechanical interconnection of the solder bump to the die through adhesion to the die passivation and attachment to a solder bump pad.

The acronym ULK stands for ultra-low-k. Dielectric materials that separate one electrically conductive portion of an integrated circuit from another are often characterized in terms of their dielectric constant (k). A low-k dielectric has a dielectric constant less than that of silicon dioxide (i.e., 3.9). An ELK material has a dielectric constant less than that of a low-k material (e.g., 2.2<k<2.5). A ULK material has a dielectric constant less than that of an ELK material.

I/O terminals were traditionally formed by way of metal pads along the periphery of an IC. These pads were then electrically connected to conductive pathways on a package by wires. Such wires, typically made of gold, have been referred to as bond wires, and the process of connecting the pads to the package has been referred to as wire bonding.

For many years wire bonding the pads, which were formed along the periphery of an IC, to connection points on a package was adequate to service the required number of I/O terminals. However, as the number of required I/O terminals reached into the hundreds, a form of I/O connection that allowed substantially the whole surface of an IC, and not only the periphery, to be available for I/O connections became popular. This form of I/O connection is known in the industry as controlled collapse chip connection, or C4. The expression “flip chip” has also been used to refer to the C4 I/O connection structures and methods.

Integrated circuits having a controlled collapse chip connection I/O configuration typically have hundreds of terminals, often referred to as bumps, that are formed on the surface of the IC. The bumps are attached to conductive material in the IC so that signals can be communicated between the IC and components that are external to the IC. The conductive material is generally a metal, such as aluminum or copper, and this metal is further interconnected with other metal lines or interconnect structures of the IC. After the bumps are formed on the IC, they are mated to corresponding connection points in a package. Subsequently, a material, such as an epoxy, is used to fill the gaps between the bumps to complete the assembly process.

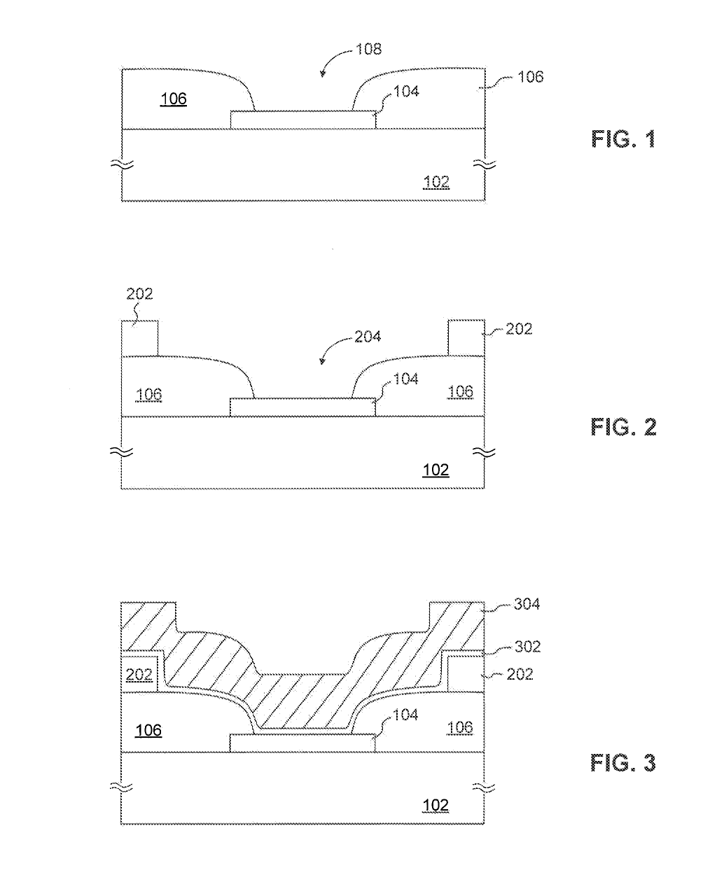

FIGS. 1-12 illustrate processes for forming the load redistribution interconnection bumps of the present invention, and interconnection between a chip and a package substrate. The structures illustrated in the figures are not necessarily drawn to scale, but rather illuminate the novel aspects of the present invention. Such schematic representations of microelectronic structures are common in this field and are well understood by those skilled in the art.

Referring to FIG. 1, a portion of a wafer having a substrate 102, a plurality of integrated circuits fabricated thereon, with a topside passivation layer 106 covering the wafer with the exception of pad openings 108 in topside passivation layer 106, each pad opening 108 exposing a portion of a bond pad 104. In typical embodiments, pad 104 is aluminum, and topside passivation layer 106 is silicon nitride. However, the present invention is not limited to a specific pairing of pad and topside materials. Further, the present invention is not limited in any way by the particular functionality of the aforementioned integrated circuits. FIG. 1 does not show details of any integrated circuits other than bond pad 104 and topside passivation 106.

FIG. 2 shows the structure of FIG. 1 after a first dielectric layer 202 has been formed over topside 106 and exposed bond pads 104, and then patterned to open a trench 204, trench 204 having dimensions that substantially define the dimensions of a force-redistributing base of an interconnection bump in accordance with the present invention. In some embodiments dielectric 202 is a photoresist material and the trench is defined by a mask. If a negative photoresist is used then the exposed portion will be polymerized and remain on the surface after the resist is developed, baked, and the surface cleaned. Similarly, if a positive resist is used then the exposed portions are depolymerized and wash away. Manufacturers will choose between light field masks and dark field masks to best suit their designs and chose of photoresist polarity.

In other embodiments, dielectric layer 202 may be a hardmask, in which case, it is typically applied as a blanket layer and a photoresist is applied over the hardmask material. Once the photoresist is patterned, the exposed portions of the hardmask are etched, and the resist is then typically removed. Layer 202 can be any material that is suitable to provide a trench for the formation of an electrically conductive force-redistributing base structure.

FIG. 3 shows the structure of FIG. 2 after a seed layer 302 has been formed on the exposed surfaces of the wafer, and a Cu metal layer 304 has been plated up over seed layer 302.

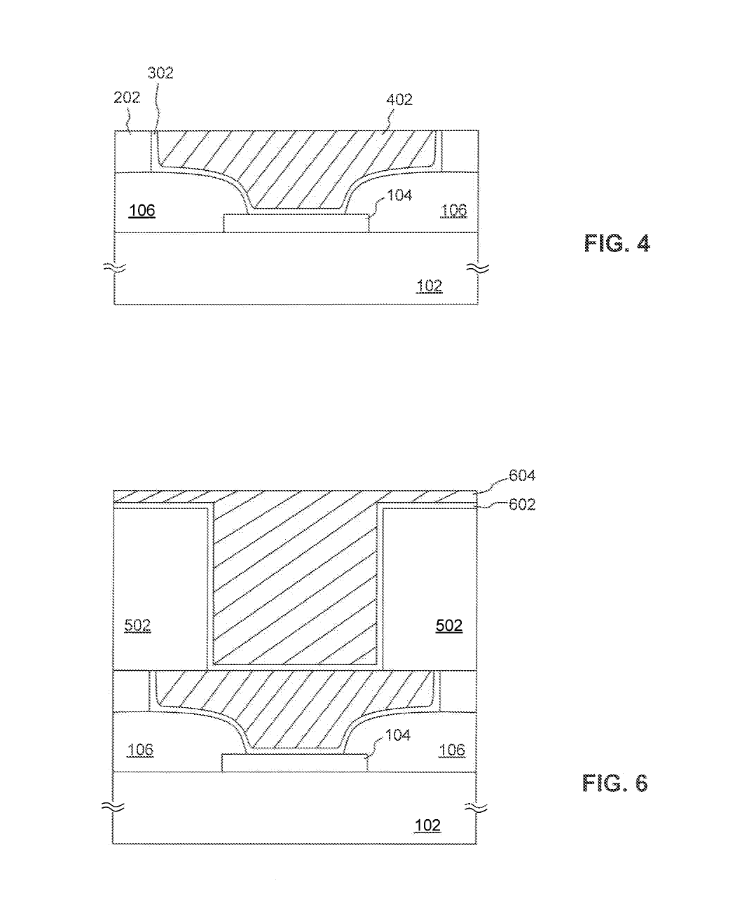

FIG. 4 shows the structure of FIG. 3 after excess Cu has been removed, leaving Cu in trench 204 in the desired dimensions for a force-redistributing base 402 of an interconnection bump in accordance with the present invention.

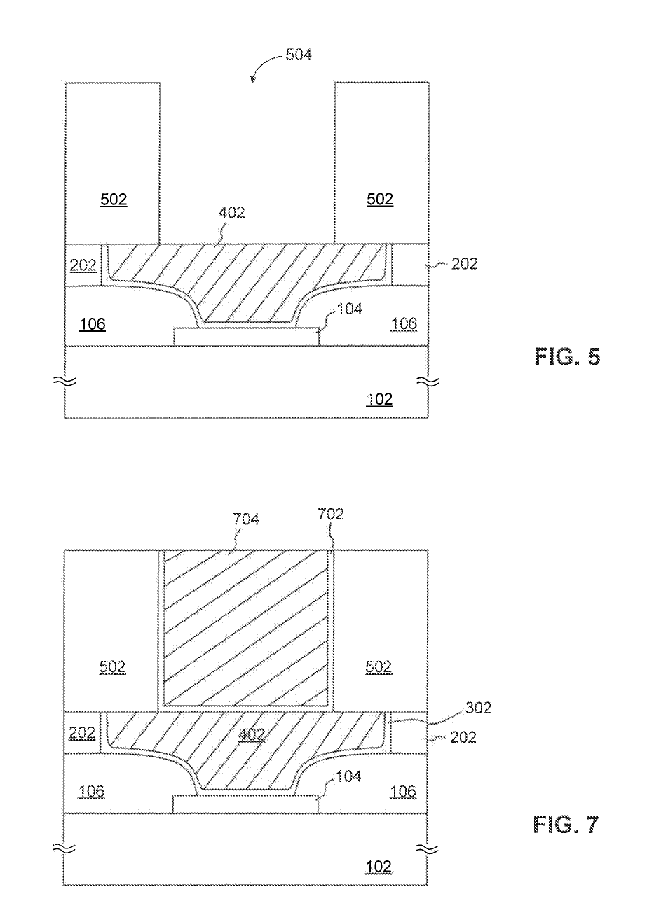

FIG. 5 shows the structure of FIG. 4 after a second dielectric layer 502 has been formed over the exposed surfaces of the wafer, i.e., the exposed surface of first dielectric layer 202 and the exposed surface of the force-redistributing base structure 402, and then patterned to open a trench 504, trench 504 having dimensions that substantially define the dimensions of a pillar of an interconnection bump in accordance with the present invention. In some embodiments dielectric 502 is a photoresist material and the trench is defined by a mask. If a negative photoresist is used then the exposed portion will be polymerized and remain on the surface after the resist is developed, baked, and the surface cleaned. Similarly, if a positive resist is used then the exposed portions are depolymerized and washed away. Manufacturers will choose between light field masks and dark field masks to best suit their designs and chose of photoresist polarity. In other embodiments, dielectric layer 502 may be a hardmask, in which case, it is typically applied as a blanket layer and a photoresist is applied over the hardmask material. Once the photoresist is patterned the exposed hardmask is etched, and the resist is then typically removed. Layer 502 can be any material that is suitable to provide a trench for the formation of an electrically conductive pillar that forms part of an interconnection bump.

FIG. 6 shows the structure of FIG. 5 after a seed layer 602 has been formed on the exposed surfaces of the wafer, i.e., second dielectric layer 502 and that portion of the force-redistributing base exposed by the trench in second dielectric layer 502, and a Cu metal layer 604 has been plated up over seed layer 602.

FIG. 7 shows the structure of FIG. 6 after excess Cu has been removed, leaving Cu in the trench of second dielectric layer 502 in the dimensions that are desired for a pillar 704 of the interconnection bump. It is noted that force redistributing base 402 is wider than pillar 704. It is further noted that both force-redistributing base 402, and pillar 704 may have any suitable shape in the x-y plane. The x-y plane that set of planes parallel to the surface of wafer substrate 102. By way of illustration and not limitation, the shape in the x-y plane of force-redistributing base 402 may be round, rectangular, or polygonal. Similarly, the shape in the x-y plane of pillar 704 may be round, rectangular, or polygonal. The shape in the x-y plane of force-redistributing base 402 and pillar 704 may be different from each other.

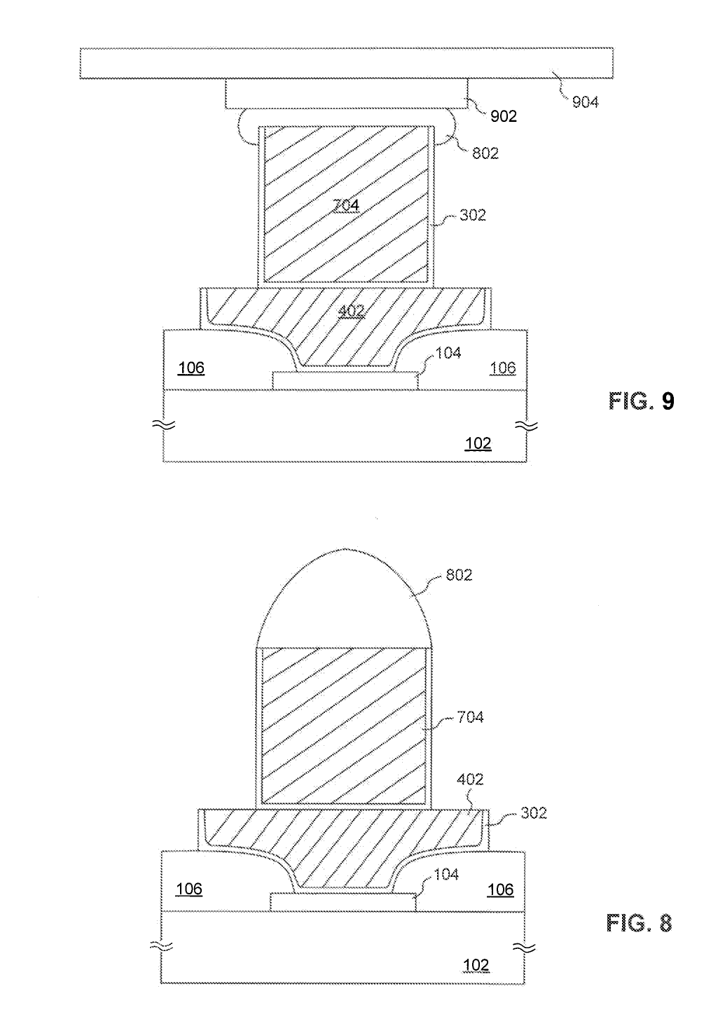

FIG. 8 shows the structure of FIG. 7 after a solder cap 802 has been formed on the top surface of pillar 704 and the second and first dielectric layers 502, 202 have been etched away.

It is noted that the interconnection structure of the present invention is typically formed at the wafer-level. The wafer is then singulated so that individual chips can be connected to a substrate.

FIG. 9 shows the structure of FIG. 8 after a contact terminal 902 of a substrate 904 is bonded with solder cap 802. Solder cap 802 is laterally deformed during the connection process in which contact terminal 902 and pillar 704 are soldered. Contact terminal 902 is electrically conductive but it material composition can be any suitable electrically conductive material or combination of materials that will also bond with the solder. Substrate 904, may be a printed circuit board or similar structure (often made FR4 but not require to be), a ceramic substrate, an interposer, a chip package, or even another chip. In a chip to chip connection, the connection may be between the interconnection structure and the bond pads of the other chip, or between the interconnection structure and the through-silicon-vias (TSVs) of the other chip.

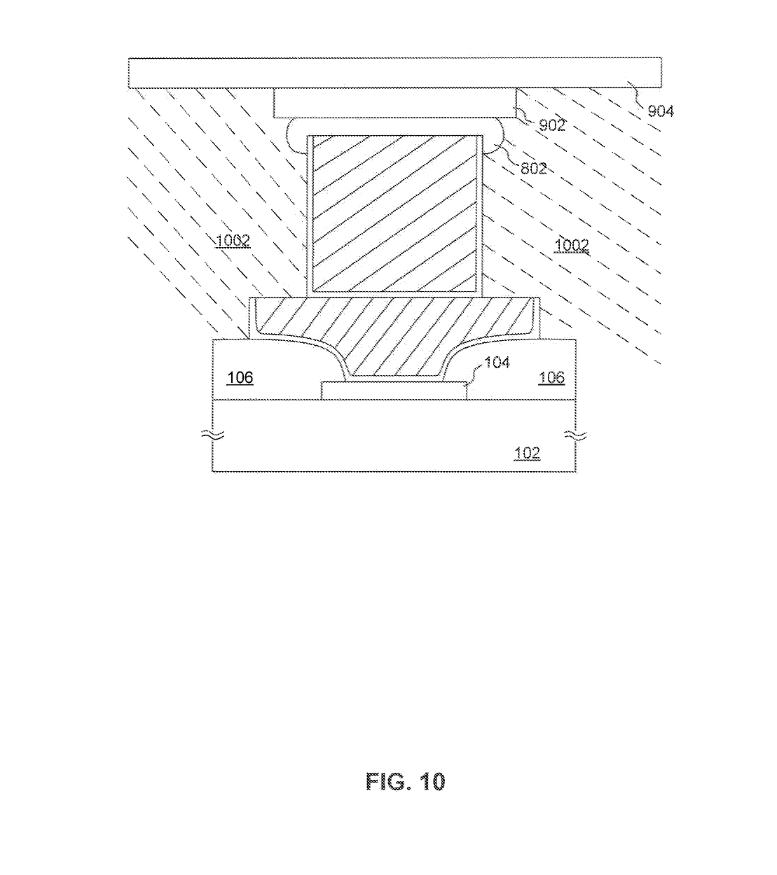

FIG. 10 shows the structure of FIG. 9 after an underfill material 1002 has been disposed between substrate 904 and the integrated circuit.

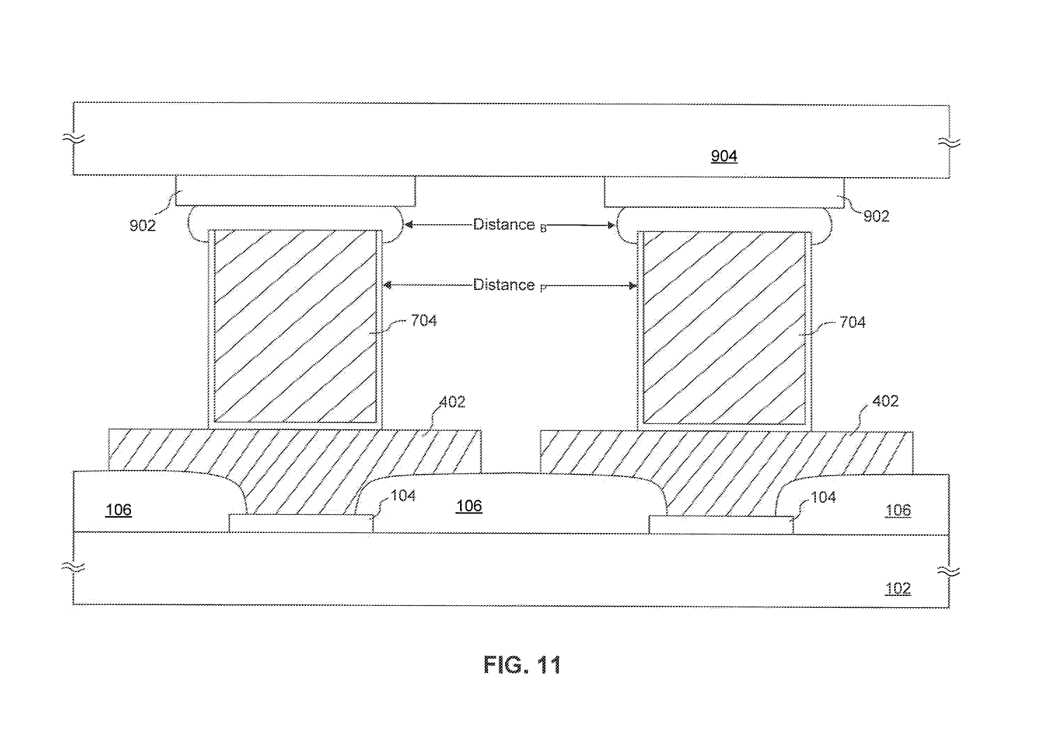

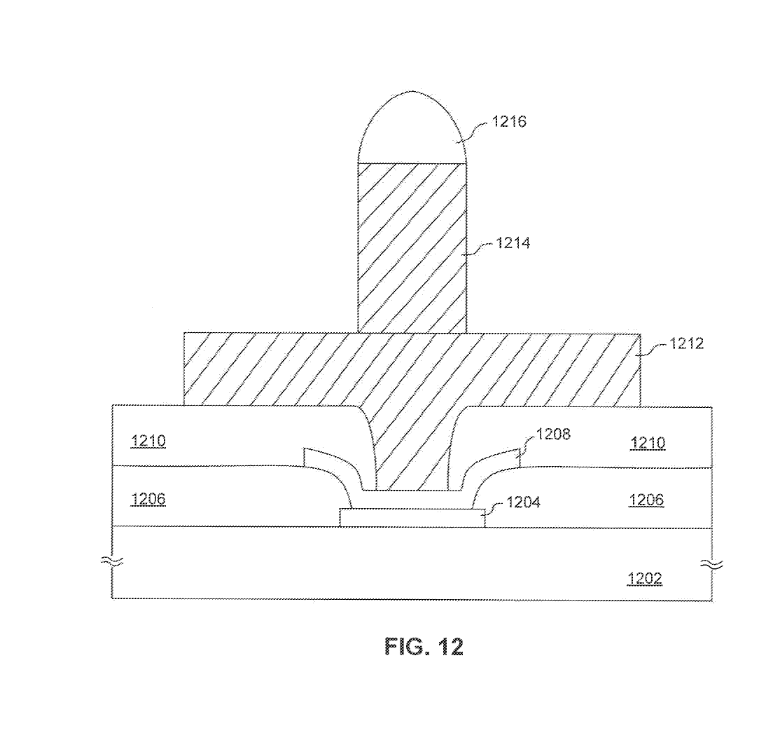

FIG. 11 shows an assembly similar to that of FIG. 9 where two base/column/cap (402/704/802) structures are shown bonded with a corresponding pair of connection terminals 902 of a substrate 904, and further illustrating the relative spacings of the columns (Distance_{P}) and the after-bonding dimensions between the solder caps (Distance_{B}).

FIG. 12 is a cross-sectional view of another embodiment of the present invention wherein a polymer passivation layer 1210 is disposed between a topside passivation layer 1206 and the underside of the wing sections of a base portion 1212 of the interconnect bump in accordance with the present invention. A wafer 1202 has a plurality of integrated circuits formed thereon. In FIG. 12, the details of these circuits are not shown since the present invention is not related to the particular function of the circuitry. A bond pad 1204 is formed, typically of aluminum or an aluminum alloy, on an upper surface of the wafer, and a topside passivation layer 1206, typically silicon nitride, is formed over the surface of the wafer. Pad openings are subsequently formed by conventional photolithographic means to expose a portion of bond pads 1204. A barrier layer 1208, such as but not limited to titanium (Ti), is formed over the passivated wafer and then patterned so that bond pads 1204 are covered, and the Ti layer 1208 also extends upwardly and outwardly over the edges of the pad openings. A second passivation layer 1210 is formed over the top surface of the wafer and then patterned to provide an opening to Ti barrier layer 1208. A Cu seed layer is then formed on Ti layer 1208. A force-redistributing base section 1212 is then formed by conventional Cu plating. A Cu pillar 1214 is disposed on force-redistributing base section 1212, and a solder cap 1216 is disposed over the distal end of pillar 1214.

In one illustrative embodiment, a method of producing an interconnection structure, includes forming a pedestal trench superjacent a bond pad, the bond pad disposed on a wafer; forming an electrically conductive pedestal having dimensions substantially defined by the pedestal trench, the pedestal electrically connected to the bond pad; forming a pillar trench superjacent the pedestal; forming an electrically conductive pillar having dimensions substantially defined by the pillar trench, the pillar electrically connected to the pedestal; and forming a solder cap on an exposed surface of the pillar; wherein the cross sectional area of the pillar, taken in a plane parallel to the wafer, is less than the cross sectional area of the pedestal, taken in a plane parallel to the wafer.

In another illustrative embodiment, a method of assembly includes providing an integrated circuit having a plurality of bond pads, each bond pad having a pedestal disposed thereon, each pedestal having a first cross-sectional area, each pedestal having a pillar disposed thereon, each pillar having a second cross-sectional area, each pillar having a solder cap disposed thereon; aligning at least two solder caps to a corresponding two connection terminals on a substrate; positioning the integrated circuit and the substrate relative to each other such that the solder caps and connection terminals are in contact with each other; and forming a soldered connection between the pillars of the integrated circuit and the connection terminals of the substrate; wherein the each pedestal is electrically connected to the bond pad upon which it is disposed; each pillar is electrically connected to the pedestal upon which it is disposed, and the second cross-sectional area is less than the first cross-sectional area.

In a still further embodiment, an electronic product, includes an integrated circuit having a plurality of bond pads, each bond pad having a pedestal disposed thereon and electrically connected thereto, each pedestal having a first cross-sectional area, each pedestal having a pillar disposed thereon and electrically connected thereto, each pillar having a second cross-sectional area, wherein the second cross-sectional area is less than the first cross-sectional area and wherein the pillars have a predetermined spaced apart relationship to each other; and a substrate having a plurality of connection terminals, the plurality of connection terminals having a spaced apart relationship to each other, and the spaced apart relationship of the connection terminals corresponds to the predetermined spaced apart relationship of the pillars; wherein the pillars and the connection terminals are electrically coupled to each other.

### CONCLUSION

It is to be appreciated that the Detailed Description section, and not the Abstract of the Disclosure, is intended to be used to interpret the claims. The Abstract of the Disclosure may set forth one or more, but not all, exemplary embodiments of the invention, and thus, is not intended to limit the invention and the subjoined Claims in any way.

It will be apparent to those skilled in the relevant art(s) that various changes in form and detail can be made therein without departing from the spirit and scope of the invention. Thus the invention should not be limited by any of the above-described exemplary embodiments, but should be defined only in accordance with the subjoined Claims and their equivalents.

What is claimed is:

1. A method of forming a bump structure, comprising:
providing a wafer, the wafer having a topside passivation layer with a plurality of openings therein to expose a corresponding plurality of bonds pads;
disposing a first hard-mask layer over the wafer such that the first hard-mask layer covers the topside passivation layer and the bond pads;
patterning the first hard-mask layer to form a plurality of trench openings, each trench opening exposing at least a portion of a bond pad;
forming a base structure in each of the trenches in the first hard-mask layer, each base structure having an exposed top surface;
disposing a second hard-mask layer over the wafer such that the second hard-mask layer covers the first hard-mask layer and the exposed surface of each base structure;
patterning the second hard-mask layer to form a plurality of trench openings, each trench opening exposing at least a portion of at least one of the base structures;
forming a pillar structure in each of the trenches in the second hard-mask layer, each pillar structure having an exposed top surface; and
disposing a solder cap on the exposed surface of at least one pillar structure.

2. The method of claim 1, wherein the base structure is a force-redistributing base structure.

3. The method of claim 2, the bond pad comprises aluminum and the force-redistributing base structure comprises copper.

4. The method of claim 3, wherein the topside layer comprises silicon nitride.

5. The method of claim 2, wherein the trench in the first hardmask substantially defines the dimensions of the force redistributing base structure.

6. The method of claim 2, wherein the trench in the second hardmask substantially defines the dimensions of the pillar.

7. The method of claim 6, wherein the pillar comprise copper.

8. The method of claim 1, the solder cap laterally deforms under heat and pressure.

9. A method of producing an interconnection structure, comprising:
forming a base trench superjacent a bond pad, the bond pad disposed on a wafer;
forming an electrically conductive base having dimensions substantially defined by the base trench, the base electrically connected to the bond pad;
forming a pillar trench superjacent the base;
forming an electrically conductive pillar having dimensions substantially defined by the pillar trench, the pillar electrically connected to the base; and
forming a solder cap on an exposed surface of the pillar;
wherein the cross sectional area of the pillar, taken in a plane parallel to the wafer, is less than the cross sectional area of the base, taken in a plane parallel to the wafer.

10. The method of claim 9, wherein the base comprises Cu, and the pillar comprise Cu.

11. A method of assembly, comprising:
providing an integrated circuit having a plurality of bond pads, each bond pad having a force-redistributing base structure disposed thereon, each force-redistributing base structure having a first cross-sectional area, each force-redistributing base structure having a pillar disposed thereon, each pillar having a second cross-sectional area, each pillar having a solder cap disposed thereon;
aligning at least two solder caps to a corresponding two connection terminals on a substrate;
positioning the integrated circuit and the substrate relative to each other such that the solder caps and connection terminals are in contact with each other; and
forming a soldered connection between the pillars of the integrated circuit and the connection terminals of the substrate;
wherein the each force-redistributing base structure is electrically connected to the bond pad upon which it is disposed; each pillar is electrically connected to the pedestal upon which it is disposed, and the second cross-sectional area is less than the first cross-sectional area.

12. The method of claim 16, wherein the force-redistributing base structures comprise Cu and the pillars comprise Cu.

13. The method of claim 16, wherein the substrate is selected from the group consisting of a printed circuit board, a ceramic substrate, an interposer, a chip package, a bond pad interface of a chip, and a through-silicon-via interface of a chip.

14. An electronic product, comprising:
an integrated circuit having a plurality of bond pads, each bond pad having a force-redistributing base structure disposed thereon and electrically connected thereto, each force-redistributing base structure having a first cross-sectional area, each force-redistributing base structure having a pillar disposed thereon and electrically connected thereto, each pillar having a second cross-sectional area, wherein the second cross-sectional area is less than the first cross-sectional area and wherein the pillars have a predetermined spaced apart relationship to each other; and
a substrate having a plurality of connection terminals, the plurality of connection terminals having a spaced apart relationship to each other, and the spaced apart relationship of the connection terminals corresponds to the predetermined spaced apart relationship of the pillars;
wherein the pillars and the connection terminals are electrically coupled to each other.

15. The electronic product of claim 20, wherein the force-redistributing base structure comprises copper, the pillar comprises copper, and the electrical coupling between corresponding pillars and connection terminals is formed by solder.
